(19) United States
(12) Patent Application Publication
(10) Pub. No.: US 2024/0230231 A1
(43) Pub. Date: Jul. 11, 2024

(54) VERTICAL DUAL-CHAMBER ANNEALING DEVICE

(71) Applicant: Naidun-tech Co., Ltd., Hsinchu City (TW)

(72) Inventors: Cheng-Hsiung LEE, Kaohsiung (TW); Chun-Hung HUNG, Kaohsiung (TW); Chun-Hung HUNG, Kaohsiung (TW); Fu-Chieh HSU, Kaohsiung (TW)

(21) Appl. No.: 18/404,917

(22) Filed: Jan. 5, 2024

(30) Foreign Application Priority Data
Jan. 6, 2023 (TW) 112100497

(51) Int. Cl. F27B 5/02; H05B 3/62

(52) U.S. Cl. CPC F27B 5/02; H05B 3/62; H01L 21/67109

(57) ABSTRACT

A vertical dual-chamber annealing device is provided. The vertical dual-chamber annealing device includes an outer chamber unit, an inner chamber body, a temperature control unit, a supporting structure, and a gas-tight seal structure. The inner chamber body can be moved upward, such that the inner chamber body can be located in the outer chamber unit and supported by the supporting structure. After the supporting of the supporting structure is removed, the inner chamber body is moved downward and separated from the outer chamber unit. Therefore, an arrangement of the inner chamber body and the outer chamber unit can increase the convenience of cleaning and replacing the inner chamber body. The structure of the inner chamber body can enhance the uniformity of a reaction temperature. The gas-tight seal structure isolates an inert gas and a reactive gas, which is beneficial to the recovery and the reuse of the reactive gas.

### RELATED APPLICATIONS

This application claims priority to Taiwan Application Serial Number 112100497, filed Jan. 6, 2023, which is herein incorporated by reference.

### BACKGROUND

### Field of Invention

The present disclosure relates to an annealing device, and more particularly, to a vertical dual-chamber annealing device.

### Description of Related Art

In a semiconductor manufacturing process, a heat treatment can be performed on a semiconductor material in a reactive gas environment to reduce the number of dangling bonds in a semiconductor device and to enhance performance of the semiconductor device. In the heat treatment process, the temperature or time of the heat treatment can be reduced to enhance efficiency by increasing the pressure.

The existing high pressure annealing unit includes an outer chamber body, an inner chamber body, and a pressure control valve. The inner chamber body is located within the outer chamber body. The pressure control valve is fixed on a top of the outer chamber body, and communicates with an outer chamber of the outer chamber body and an inner chamber of the inner chamber body. The inner chamber is filled with a reactive gas. The outer chamber is filled with an inert gas. After the annealing process of the semiconductor material in the high pressure annealing unit is completed, the reactive gas and inert gas are mixed and discharged from the pressure control valve, such that it is difficult to recover and reuse the reactive gas. In addition, an upper portion of the inner chamber body is fixed to the outer chamber body by the pressure control valve, such that it is inconvenient to clean and replace the inner chamber body, and the uniformity of the reaction temperature of the inner chamber body is adversely affected.

### SUMMARY

Therefore, one objective of the present disclosure is to provide a vertical dual-chamber annealing device to reduce the difficulty of recovering and reusing the reactive gas and the inconvenience of cleaning and replacing the inner chamber body, and enhance the uniformity of the reaction temperature of the inner chamber body.

According to the aforementioned objective, the present disclosure provides a vertical dual-chamber annealing device. The vertical dual-chamber annealing device includes an outer chamber unit, an inner chamber body, a temperature control unit, a supporting structure, and a gas-tight seal structure. The outer chamber unit includes an outer chamber body, an outer chamber, a first gas injection port, a first gas discharge port, a second gas injection port, a second gas discharge port, a cooling jacket, a lower cover assembly, and plural through holes. The outer chamber is formed in the outer chamber body and is configured to accommodate an inert gas. The first gas injection port is disposed on the outer chamber body and is configured for injecting of the inert gas into the outer chamber. The first gas discharge port is disposed on the outer chamber body and is configured for discharging of the inert gas out the outer chamber. The second gas injection port is disposed on the outer chamber body. The second gas discharge port is disposed on the outer chamber body. The cooling jacket is disposed on the outer chamber body. The lower cover assembly is disposed on a bottom of the outer chamber body and is configured to open and close the outer chamber body. The through holes radially penetrate the outer chamber body. The inner chamber body is located in the outer chamber. The inner chamber body includes an inner chamber, a closed end, an open end, and a flange. The inner chamber is formed in the inner chamber body and is configured to accommodate a reactive gas. The reactive gas is injected from the second gas injection port and discharged from the second gas discharge port. The closed end is located on one end of the inner chamber body. The open end is located on another end of the inner chamber body and faces the lower cover assembly. The flange is disposed on an outer side surface of the inner chamber body. The temperature control unit is located between the outer chamber body and the inner chamber body and is configured to increase or decrease a temperature in the inner chamber. The supporting structure is located between the outer chamber body and the inner chamber body, and is configured to support the flange, be connected to the outer chamber body, and fix the inner chamber body in the outer chamber body. The supporting structure includes a flange fastener, plural moving shafts, and plural shaft sealing rings. The flange fastener is located between the outer chamber body and the inner chamber body, and is configured to support the flange and limit a movement of the inner chamber body. The moving shafts are respectively disposed in the through holes of the outer chamber body, are configured to support the flange fastener, and be connected to the outer chamber body. The shaft sealing rings are disposed in the outer chamber body and respectively surround the moving shafts, and are configured to respectively seal the through holes. The gas-tight seal structure is located between the outer chamber body and the inner chamber body, and is configured to isolate the inert gas and the reactive gas.

According to one embodiment of the present disclosure, an internal pressure that the outer chamber unit can bear is 10 bar to 1000 bar.

According to one embodiment of the present disclosure, the cooling jacket is a component made of metal, and is configured to cool the outer chamber body and the shaft sealing rings.

According to one embodiment of the present disclosure, the lower cover assembly includes a cover plate, a plate sealing ring, and a lower cover fastener. The cover plate is disposed on the bottom of the outer chamber body and is configured to lift the inner chamber body. The plate sealing ring is disposed on the cover plate and abuts against the outer chamber, and is configured to seal the reactive gas, such that the reactive gas does not leak through a gap between the cover plate and the outer chamber. The lower cover fastener carries the cover plate and is connected to the outer chamber, and is configured to fix the cover plate.

According to one embodiment of the present disclosure, the cover plate is a component made of metal, and the lower cover fastener is a clamp.

According to one embodiment of the present disclosure, a top surface of the cover plate is provided with plural positioning pins, and the positioning pins are configured to support the flange fastener.

According to one embodiment of the present disclosure, a material of the plate sealing ring is selected from a group consisting of metallic materials, non-metallic materials, and combinations thereof.

According to one embodiment of the present disclosure, the material of the plate sealing ring includes stainless steel, nickel-based alloy, rubber, polytetrafluoroethylene (PTFE), polyfluoroalkoxy (PFA), a combination of polytetrafluoroethylene and carbon fiber, a combination of polytetrafluoroethylene and carbon, or a combination of polytetrafluoroethylene and metal powder.

According to one embodiment of the present disclosure, a longitudinal cross-sectional shape of the plate sealing ring is circular, U-shaped, X-shaped, W-shaped, quadrilateral, or wavy-shaped.

According to one embodiment of the present disclosure, the inner chamber body is a component made of a non-metallic material.

According to one embodiment of the present disclosure, a material of the inner chamber body includes quartz, ceramics, glass, graphite, or silicon carbide.

According to one embodiment of the present disclosure, the inner chamber body is a component made of a corrosion-resistant metal material.

According to one embodiment of the present disclosure, a material of the inner chamber body includes nickel-based alloy or stainless steel.

According to one embodiment of the present disclosure, the temperature control unit includes a heating element and a heat insulating material. The heating element is disposed on the outer side surface of the inner chamber body, and is configured to heat the inner chamber body to increase the temperature in the inner chamber to an annealing temperature. The heat insulating material is located on an outer side surface of the heating element and is configured to increase a heating efficiency of the heating element.

According to one embodiment of the present disclosure, the temperature control unit further includes a cooling spiral pipe. The cooling spiral pipe is disposed on the heat insulating material and is configured to decrease the temperature in the inner chamber.

According to one embodiment of the present disclosure, a cooling fluid in the cooling spiral pipe is cooling water, inert gas, or air.

According to one embodiment of the present disclosure, the supporting structure includes plural moving shaft driving members. The moving shaft driving members are located on an outer side surface of the outer chamber body and are respectively connected to the moving shafts.

According to one embodiment of the present disclosure, the flange fastener includes a lower clamp, an upper clamp, and a locking member. The lower clamp is located between the outer chamber body and the inner chamber body, and under the flange. The upper clamp is disposed above the lower clamp. The locking member passes through the upper clamp and is screwed into the lower clamp, and is configured to fix the upper clamp. The flange is clamped by the lower clamp and the upper clamp, and the moving shafts abut against the upper clamp.

According to one embodiment of the present disclosure, the gas-tight seal structure includes plural gas-tight seal rings. Portions of the gas-tight seal rings are located between the lower clamp and the inner chamber body. Remaining portions of the gas-tight seal rings are located between the lower clamp and the outer chamber body.

According to one embodiment of the present disclosure, the flange fastener includes a flange fastener body and a fixing bolt. The flange fastener body is located between the outer chamber body and the inner chamber body and carries the flange. The fixing bolt penetrates the flange fastener body and is screwed into the outer chamber body.

According to one embodiment of the present disclosure, the gas-tight seal structure includes an gas-tight seal ring, and the gas-tight seal ring is located between the flange and the inner chamber body.

According to one embodiment of the present disclosure, a material of the gas-tight seal ring includes stainless steel, nickel-based alloy, rubber, polytetrafluoroethylene, polyfluoroalkoxy, a combination of polytetrafluoroethylene and carbon fiber, a combination of polytetrafluoroethylene and carbon, or a combination of polytetrafluoroethylene and metal powder.

According to one embodiment of the present disclosure, a longitudinal cross-sectional shape of the gas-tight seal ring is circular, U-shaped, X-shaped, W-shaped, quadrilateral, or wavy-shaped.

According to one embodiment of the present disclosure, the outer chamber unit includes a cooling channel. The cooling channel is formed in the outer chamber body and is configured to cool the gas-tight seal structure.

According to the aforementioned description, it is known that the upper end of the inner chamber body forms a closed end, which can enhance the uniformity of the reaction temperature. The inner chamber body can be moved upward and into the outer chamber body, and the supporting structure can support the inner chamber body and fix the inner chamber body in the outer chamber body, such that when the lower cover assembly is opened, the inner chamber body will not fall off. After the supporting of the supporting structure is removed, the inner chamber body can be moved downward and separated from the outer chamber unit. Therefore, with the inner chamber body and the supporting structure, the convenience of cleaning and replacing of the inner chamber body is increased. The gas-tight seal structure isolates the inert gas and the reactive gas, which is beneficial to the recovery and the reuse of the reactive gas.

### BRIEF DESCRIPTION OF THE DRAWINGS

In order to make the above and other objectives, features, advantages, and embodiments of the present disclosure more obvious and understandable, the accompanying drawings are described as follows:

FIG. 1 is a schematic cross-sectional view of a vertical dual-chamber annealing device in accordance with a first embodiment of the present disclosure;

FIG. 2A to FIG. 2C are schematic diagrams showing an installation process of an inner chamber body of the vertical dual-chamber annealing device in accordance with the first embodiment of the present disclosure;

FIG. 3 is a schematic cross-sectional view of a vertical dual-chamber annealing device in accordance with a second embodiment of the present disclosure;

FIG. 4 is a partially enlarged schematic cross-sectional view of a vertical dual-chamber annealing device in accordance with a third embodiment of the present disclosure;

FIG. 5A to FIG. 5C are schematic diagrams showing an installation process of an inner chamber body of the vertical dual-chamber annealing device in accordance with the third embodiment of the present disclosure;

FIG. 6 is a partially enlarged schematic cross-sectional view of a vertical dual-chamber annealing device in accordance with a fourth embodiment of the present disclosure;

FIG. 7A to FIG. 7C are schematic diagrams showing an installation process of an inner chamber body of the vertical dual-chamber annealing device in accordance with the fourth embodiment of the present disclosure;

FIG. 8 is a partially enlarged schematic cross-sectional view of a vertical dual-chamber annealing device in accordance with a fifth embodiment of the present disclosure;

FIG. 9A to FIG. 9C are schematic diagrams showing an installation process of an inner chamber body of the vertical dual-chamber annealing device in accordance with the fifth embodiment of the present disclosure;

FIG. 10 is a partially enlarged schematic cross-sectional view of a vertical dual-chamber annealing device in accordance with a sixth embodiment of the present disclosure; and

FIG. 11 is a partially enlarged schematic cross-sectional view of a vertical dual-chamber annealing device in accordance with a seventh embodiment of the present disclosure.

### DETAILED DESCRIPTION

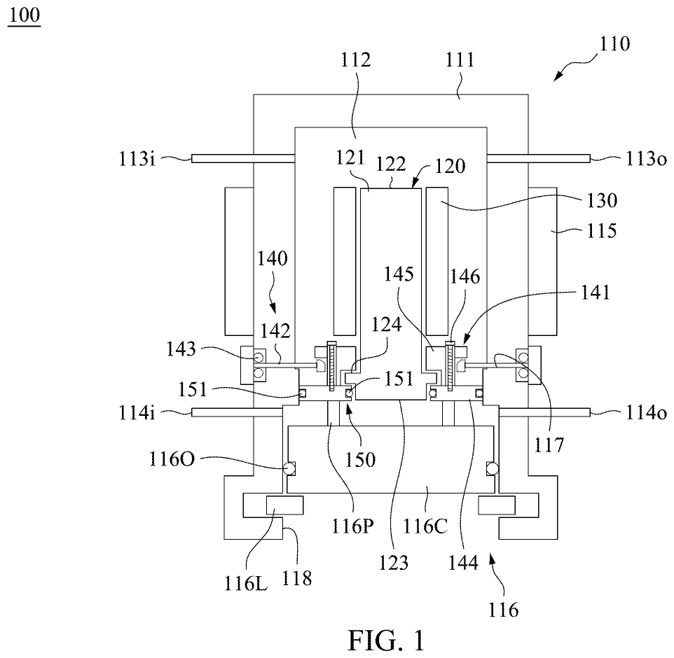

Referring to FIG. 1, FIG. 1 is a schematic cross-sectional view of a vertical dual-chamber annealing device 100 in accordance with a first embodiment of the present disclosure. The vertical dual-chamber annealing device 100 includes an outer chamber unit 110, an inner chamber body 120, a temperature control unit 130, a supporting structure 140, and a gas-tight seal structure 150.

Continuing to refer to FIG. 1, the outer chamber unit 110 can bear an internal pressure ranging from 10 bar to 1000 bar. The outer chamber unit 110 includes an outer chamber body 111, an outer chamber 112, a first gas injection port 113i, a first gas discharge port 113o, a second gas injection port 114i, a second gas discharge port 114o, a cooling jacket 115, a lower cover assembly 116, and through holes 117. The outer chamber body 111 may be a generally inverted U-shaped component in longitudinal cross-section. In other words, a lower opening 118 is formed on a bottom of the outer chamber body 111. In one example, the outer chamber body 111 may be an integral component. In one example, the outer chamber body 111 may be a combined component.

An outer chamber 112 is formed in the outer chamber body 111 and is configured to accommodate an inert gas. The first gas injection port 113i is disposed on the outer chamber body 111, and an inert gas can be injected into the outer chamber 112 through the first gas injection port 113i. The first gas discharge port 113o is disposed on the outer chamber body 111, and an inert gas can be discharged from the outer chamber 112 through the first gas discharge port 113o. In one example, the first gas injection port 113i and the first gas discharge port 113o are adjacent to a top surface of the outer chamber body 111. In one example, the first gas injection port 113i and the first gas discharge port 113o are opposite to each other. The second gas injection port 114i and the second gas discharge port 114o are both disposed on the outer chamber body 111 for the injection and discharge of a reactive gas. In one example, the second gas injection port 114i is located below the first gas injection port 113i, and the second gas discharge port 114o is located below the first gas discharge port 113o.

The cooling jacket 115 is disposed on an outer surface of the outer chamber body 111. In one example, the cooling jacket 115 is a component made of metal, and the cooling jacket 115 is used to cool the outer chamber body 111 and shaft sealing rings 143 of the supporting structure 140 located in the outer chamber body 111, such that the outer chamber body 111 and the shaft sealing rings 143 can be at appropriate operating temperatures to prevent failure. The lower cover assembly 116 is disposed on the bottom of the outer chamber body 111 and is configured to open and close the outer chamber body 111. That is, the lower cover assembly 116 controls the opening and the closing of the lower opening 118 of the outer chamber body 111. The through holes 117 radially penetrate the outer chamber body 111, that is, the through holes 117 communicate with the outer chamber 112.

In one example, the lower cover assembly 116 includes a cover plate 116C, a plate sealing ring 116O, and a lower cover fastener 116L. The cover plate 116C is disposed on the bottom of the outer chamber body 111 and is configured to lift the inner chamber body 120. The plate sealing ring 116O is disposed on the cover plate 116C and abuts against the outer chamber 112. The plate sealing ring 116O is configured to seal the reactive gas, such that the reactive gas is not leak through a gap between the cover plate 116C and the outer chamber 112. The lower cover fastener 116L carries the cover plate 116C and is connected to the outer chamber 112. The lower cover fastener 116L is configured to fix the cover plate 116C. In one example, the cover plate 116C is made of metal. In one example, a top surface of the cover plate 116C is provided with positioning pins 116P, and the positioning pins 116P are configured to support a flange fastener 141 of the supporting structure 140. The inner chamber body 120 can be placed and fixed on the positioning pins 116P. When the lower cover assembly 116 lifts the inner chamber body 120 to the outer chamber 112 and the inner chamber body 120 is not fixed to the outer chamber body 111, the positioning pins 116P can be first used to fix the position of the inner chamber body 120. In one example, the lower cover fastener 116L is a clamp, such as an integral clamp, a split clamp, an integral clamp with a fastener, a combined ring clamp, or a yoke clamp.

In one example, a material of the plate sealing ring 116O is selected from a group consisting of metallic materials, non-metallic materials, and combinations thereof. The material of the plate sealing ring 116O includes stainless steel, nickel-based alloy, rubber, polytetrafluoroethylene (PTFE), polyfluoroalkoxy (PFA), a combination of polytetrafluoroethylene and carbon fiber, a combination of polytetrafluoroethylene and carbon, or a combination of polytetrafluoroethylene and metal powder. In one example, a longitudinal cross-sectional shape of the plate sealing ring 116O is circular, U-shaped, X-shaped, W-shaped, quadrilateral, or wavy-shaped.

Continuing to refer to FIG. 1, the inner chamber body 120 is located in the outer chamber 112. Specifically, the inner chamber body 120 can be lifted and moved upward, and the inner chamber body 120 can enter the outer chamber 112 through the lower opening 118 of the outer chamber body 111. In one example, the inner chamber body 120 is a component made of a non-metallic material. A material of the inner chamber body 120 includes quartz, ceramics, glass, graphite, or silicon carbide. In one example, the inner chamber body 120 is a component made of a corrosion-resistant metal material. The material of the inner chamber body 120 includes nickel-based alloy or stainless steel.

The inner chamber body 120 includes an inner chamber 121, a closed end 122, an open end 123, and a flange 124. The inner chamber 121 is formed in the inner chamber body 120, and is configured to accommodate the reactive gas injected from the second gas injection port 114i. The reactive gas in the inner chamber 121 may be discharged through the second gas discharge port 114o. The closed end 122 is located on one end of the inner chamber body 120. The open end 123 is located on the other end of the inner chamber body 120 and faces the lower cover assembly 116. In one example, the closed end 122 and the open end 123 are located on two opposite ends of the inner chamber body 120. In one example, the closed end 122 is located on an upper end of the inner chamber body 120 and adjacent to a top surface of the outer chamber body 111. The open end 123 is located on a lower end of the inner chamber body 120 and adjacent to the lower opening 118 of the outer chamber body 111. The flange 124 is disposed on an outer side surface of the inner chamber body 120. In one example, the flange 124 surrounds the inner chamber body 120. In one example, the flange 124 is adjacent to the open end 123. In one example, there may be one flange 124, and the flange 124 cooperates with the gas-tight seal structure 150 to provide a gas-tight seal effect. In one example, there may be two flanges 124, and the flanges 124 are spaced apart from each other and are arranged up and down. The upper flange 124 can cooperate with the supporting structure 140 for supporting and fixing. The lower flange 124 cooperates with the gas-tight seal structure 150 to provide a gas-tight seal effect.

Continuing to refer to FIG. 1, the temperature control unit 130 is located between the outer chamber body 111 and the inner chamber body 120 and is configured to increase or decrease the temperature in the inner chamber 121. In one example, the temperature control unit 130 provides thermal energy to heat the inner chamber body 120, and the temperature control unit 130 may be adjacent to an outer surface of the inner chamber body 120 to reduce the loss of heat energy and increase the temperature of the inner chamber 121 to the annealing temperature.

Continuing to refer to FIG. 1, the supporting structure 140 is located between the outer chamber body 111 and the inner chamber body 120. The supporting structure 140 is configured to support the flange 124, be connected to the outer chamber body 111, and fix the inner chamber body 120 in the outer chamber body 111. The supporting structure 140 includes a flange fastener 141, moving shafts 142s, and shaft sealing rings 143. The flange fastener 141 is located between the outer chamber body 111 and the inner chamber body 120, and is configured to support the flange 124 and limit the movement of the inner chamber body 120. In one example, according to a top view of the flange fastener 141, the flange fastener 141 may be an integral annular component. In another example, according to a top view of the flange fastener 141, the flange fastener 141 may be a combined component, that is, a combined component composed of plural arc-shaped segments. In one example, the flange fastener 141 includes a lower clamp 144, an upper clamp 145, and a locking member 146. The lower clamp 144 is located between the outer chamber body 111 and the inner chamber body 120, and is located under the flange 124. The upper clamp 145 is disposed above the lower clamp 144. The locking member 146 passes through the upper clamp 145 and is screwed into the lower clamp 144 to fix the upper clamp 145. The flange fastener 141 clamps the flange 124 of the inner chamber body 120 by using the lower clamp 144 and the upper clamp 145.

Continuing to refer to FIG. 1, the moving shafts 142 are disposed in the through holes 117 of the outer chamber body 111, and are configured to support the flange fastener 141 and are connected to the outer chamber body 111. In one example, the moving shafts 142 can be manually operated, that is, the operator can manually operate the moving shafts 142 to move into or out of the outer chamber body 111. In one example, the moving shafts 142 can abut against and carry the upper clamp 145. The shaft sealing rings 143 are disposed in the outer chamber body 111 and surround the moving shafts 142. The shaft sealing rings 143 are configured to seal the through holes 117, so as to prevent the inert gas in the outer chamber 112 from leaking through the through holes 117.

Continuing to refer to FIG. 1, the gas-tight seal structure 150 is located between the outer chamber body 111 and the inner chamber body 120, and is configured to isolate the inert gas and the reactive gas. In one example, the gas-tight seal structure 150 includes two or more than two gas-tight seal rings 151. Portions of the gas-tight seal rings 151 are located between the lower clamp 144 and the inner chamber body 120, and remaining portions of the gas-tight seal rings 151 are located between the lower clamp 144 and the outer chamber body 111, such that the reactive gas and the inert gas are not mixed through the gap between the lower clamp 144 and the inner chamber body 120 or the gap between the lower clamp 144 and the outer chamber body 111. In one example, a material of the gas-tight seal rings 151 may be selected from the group consisting of metallic materials, non-metallic materials, and combinations thereof, such as stainless steel, nickel-based alloy, rubber, polytetrafluoroethylene, polyfluoroalkoxy, a combination of polytetrafluoroethylene and carbon fiber, a combination of polytetrafluoroethylene and carbon, or a combination of polytetrafluoroethylene and metal powder. In one example, a longitudinal cross-sectional shape of the gas-tight seal rings 151 may be circular, U-shaped, X-shaped, W-shaped, quadrilateral, or wavy-shaped.

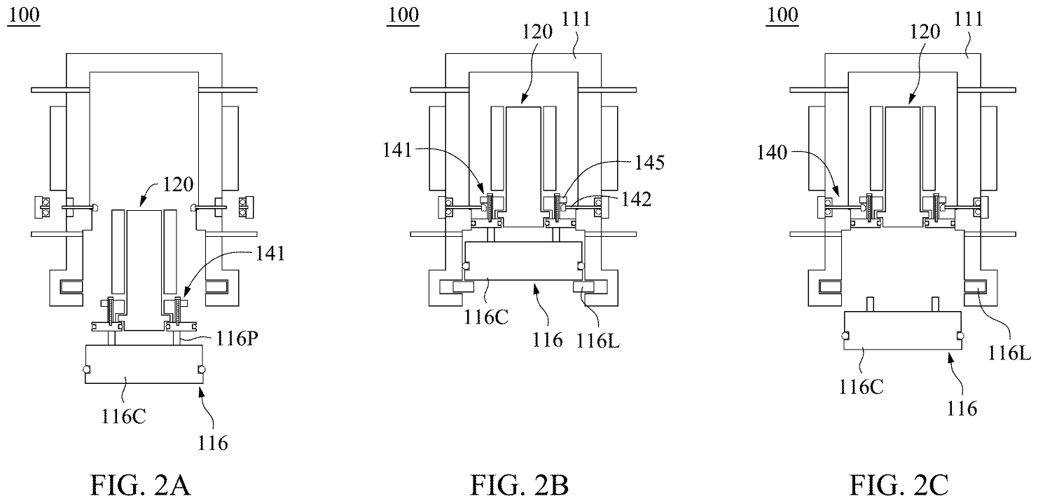

Referring to FIG. 2A to FIG. 2C, FIG. 2A to FIG. 2C are schematic diagrams showing an installation process of the inner chamber body 120 of the vertical dual-chamber annealing device 100 in accordance with the first embodiment of the present disclosure. As shown in FIG. 2A, the inner chamber body 120 is placed on the positioning pins 116P of the cover plate 116C by using the flange fastener 141. The inner chamber body 120 can be lifted by the cover plate 116C of the lower cover assembly 116. Next, as shown in FIG. 2B, after the inner chamber body 120 is moved upward to a predetermined position, the lower cover fastener 116L of the lower cover assembly 116 can be actuated to close, such that the lower cover fastener 116L protrudes to a bottom surface of the cover plate 116C to position the cover plate 116C. The operator manually operates the moving shafts 142 to move into the flange fastener 141, such that the moving shafts 142 can carry the upper clamp 145 to support the inner chamber body 120 and fix the inner chamber body 120 in the outer chamber body 111. Then, as shown in FIG. 2C, the lower cover fastener 116L of the lower cover assembly 116 can be actuated to open, such that the cover plate 116C can be moved downward and separated from the inner chamber body 120 to complete the fixing and the installation of the inner chamber body 120. Therefore, although there is no support from the cover plate 116C, the inner chamber body 120 can still be supported by the supporting structure 140 and can be fixed to the outer chamber body 111 without falling off.

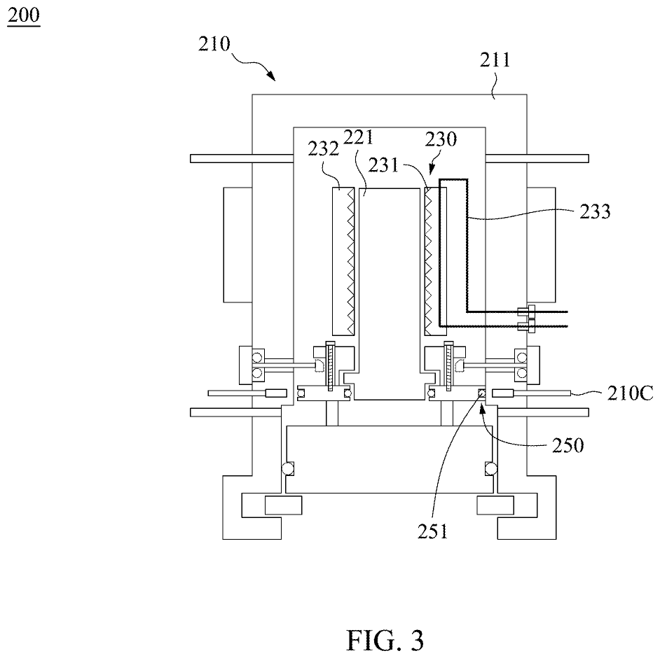

Referring to FIG. 3, FIG. 3 is a schematic cross-sectional view of a vertical dual-chamber annealing device 200 in accordance with a second embodiment of the present disclosure. A structure of the second embodiment of the present disclosure is substantially the same as that of the first embodiment, and one of the differences is that in the vertical dual-chamber annealing device 200 of the second embodiment, an outer chamber unit 210 includes a cooling channel 210C. The cooling channel 210C is formed in an outer chamber body 211 and is configured to cool a gas-tight seal structure 250. Thus, gas-tight seal rings 251 of the gas-tight seal structure 250 can be kept at an appropriate operating temperature to avoid failure due to excessively high operating temperature, such that the reactive gas and the inert gas can be reliably isolated by the gas-tight seal structure 250.

Continuing to refer to FIG. 3, another difference is that in the vertical dual-chamber annealing device 200 of the second embodiment, a temperature control unit 230 includes a heating element 231 and a heat insulating material 232. The heating element 231 is disposed on the outer side surface of the inner chamber body 120 and is configured to heat the inner chamber body 120 to increase the temperature in an inner chamber 221 to the annealing temperature. The heat insulating material 232 is located on an outer side surface of the heating element 231 and is configured to increase the heating efficiency of the heating element 231. In one example, the temperature control unit 230 further includes a cooling spiral pipe 233. The cooling spiral pipe 233 is disposed on the heat insulating material 232 and is configured to decrease the temperature in the inner chamber 221. A cooling fluid in the cooling spiral pipe 233 is cooling water, inert gas, or air. In one example, the cooling spiral pipe 233 may be a high pressure resistant cooling spiral pipe.

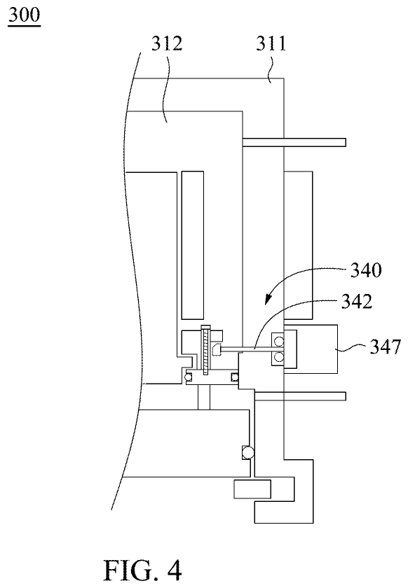

Referring to FIG. 4, FIG. 4 is a partially enlarged schematic cross-sectional view of a vertical dual-chamber annealing device 300 in accordance with a third embodiment of the present disclosure. A structure of the third embodiment of the present disclosure is substantially the same as that of the first embodiment. A difference between the two embodiments is that in the vertical dual-chamber annealing device 300 of the third embodiment, a supporting structure 340 includes plural moving shaft driving members 347. The moving shaft driving members 347 are located on an outer side surface of an outer chamber body 311 and are connected to moving shafts 342. Therefore, the moving shaft driving members 347 can drive the moving shafts 342 to move into or out of an outer chamber 312.

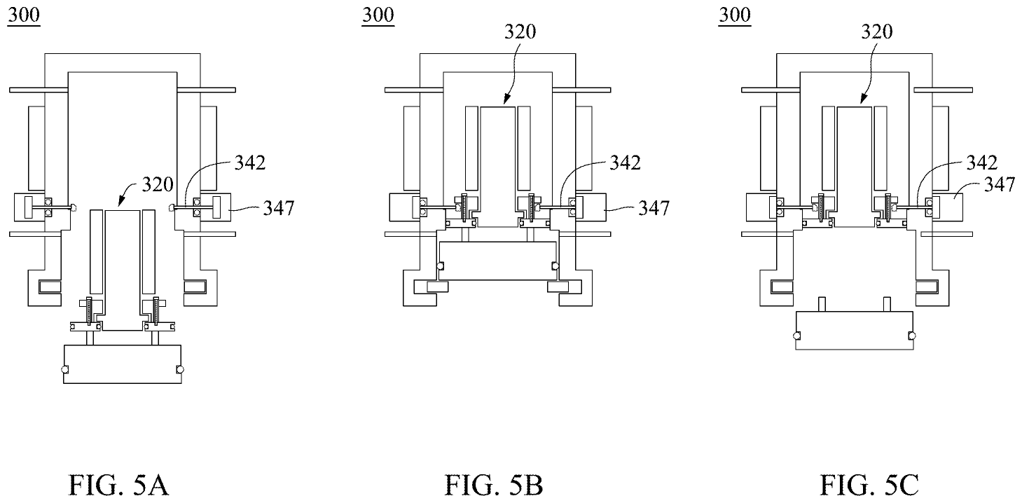

Referring to FIG. 5A to FIG. 5C, FIG. 5A to FIG. 5C are schematic diagrams showing an installation process of an inner chamber body 320 of the vertical dual-chamber annealing device 300 in accordance with the third embodiment of the present disclosure. The installation processes of the inner chamber body 120 of the vertical dual-chamber annealing device 100 of the first embodiment and the inner chamber body 320 of the vertical dual-chamber annealing device 300 of the third embodiment of the present disclosure are substantially the same. A difference between the two installation processes is that in the installation process of the inner chamber body 320 of the vertical dual-chamber annealing device 300 of the third embodiment, the moving shaft driving members 347 are used to drive the moving shafts 342 instead of the operator, such that the moving operation of the moving shafts 342 is more convenient, and the labor cost is saved.

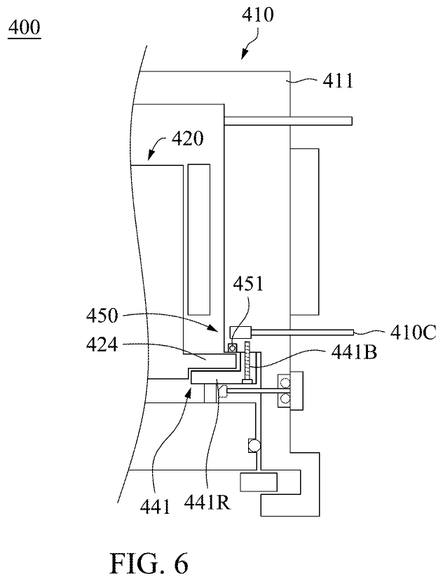

Referring to FIG. 6, FIG. 6 is a partially enlarged schematic cross-sectional view of a vertical dual-chamber annealing device 400 in accordance with a fourth embodiment of the present disclosure. A structure of the fourth embodiment of the present disclosure is substantially the same as that of the first embodiment. One difference between the two embodiments is that in the vertical dual-chamber annealing device 400 of the fourth embodiment, an outer chamber unit 410 includes a cooling channel 410C. The cooling channel 410C is formed in an outer chamber body 411 and is configured to cool a gas-tight seal structure 450. Thus, gas-tight seal rings 451 of the gas-tight seal structure 450 is kept at an appropriate operating temperature to avoid failure due to excessively high operating temperature, such that the reactive gas and the inert gas are reliably isolated by the gas-tight seal structure 450.

Continuing to FIG. 6, another difference is that in the vertical dual-chamber annealing device 400 of the fourth embodiment, a flange fastener 441 includes a flange fastener body 441R and a fixing bolt 441B. The flange fastener body 441R is located between the outer chamber body 411 and an inner chamber body 420, and the flange fastener body 441R carries a flange 424. The fixing bolt 441B penetrates the flange fastener body 441R from a bottom to a top and is screwed into the outer chamber body 411, such that the flange fastener body 441R is fixed to the outer chamber body 411. The flange 424 of the inner chamber body 420 is carried by the flange fastener body 441R, such that the inner chamber body 420 is fixed to the outer chamber body 411. The gas-tight seal rings 451 of the gas-tight seal structure 450 are located between the flange 424 and the outer chamber body 411 to isolate the inert gas and the reactive gas.

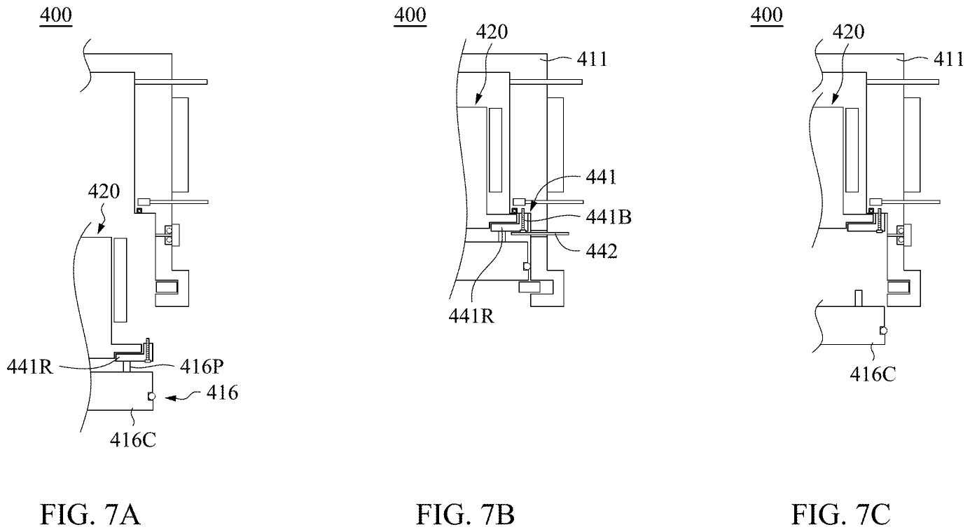

Referring to FIG. 7A to FIG. 7C, FIG. 7A to FIG. 7C are schematic diagrams showing an installation process of the inner chamber body 420 of the vertical dual-chamber annealing device 400 in accordance with the fourth embodiment of the present disclosure. As shown in FIG. 7A, the inner chamber body 420 is placed on the flange fastener body 441R, and the flange fastener body 441R is placed on positioning pins 416P of a cover plate 416C. That is, the inner chamber body 420 is placed on the positioning pins 416P through the flange fastener body 441R. The cover plate 416C of a lower cover assembly 416 can lift the inner chamber body 420. Next, as shown in FIG. 7B, after the inner chamber body 420 is moved upward to a predetermined position, the operator inserts the moving shafts 442 to positions under the flange fastener body 441R to support the flange fastener body 441R and the inner chamber body 420. Then, the fixing bolt 441B is screwed into the outer chamber body 411 to fix the flange fastener body 441R to the outer chamber body 411, such that the inner chamber body 420 is fixed to the outer chamber body 411 through the flange fastener 441. Then, as shown in FIG. 7C, the operator can extract the moving shafts 442. The cover plate 416C is moved downward and separated from the inner chamber body 420 to complete the fixing installation of the inner chamber body 420. Therefore, although there is no support from the cover plate 416C, the inner chamber body 420 can still be fixed to the outer chamber body 411 without falling off.

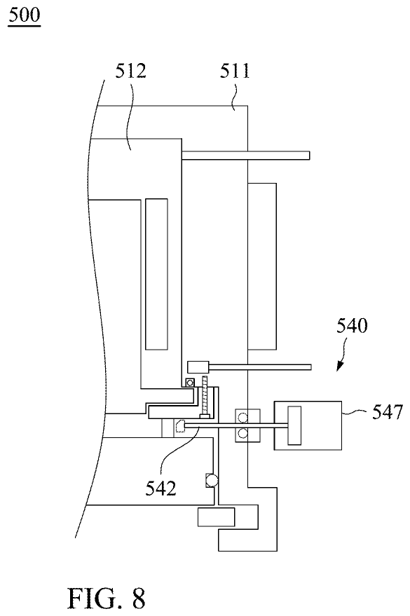

Referring to FIG. 8, FIG. 8 is a partially enlarged schematic cross-sectional view of a vertical dual-chamber annealing device 500 in accordance with a fifth embodiment of the present disclosure. A structure of the fifth embodiment of the present disclosure is substantially the same as that of the fourth embodiment. A difference between the two embodiments is that in the vertical dual-chamber annealing device 500 of the fifth embodiment, a supporting structure 540 includes plural moving shaft driving members 547. The moving shaft driving members 547 are located on an outer side surface of an outer chamber body 511 and are connected to moving shafts 542. Therefore, the moving shaft driving members 547 can drive the moving shafts 542 to move into or out of an outer chamber 512.

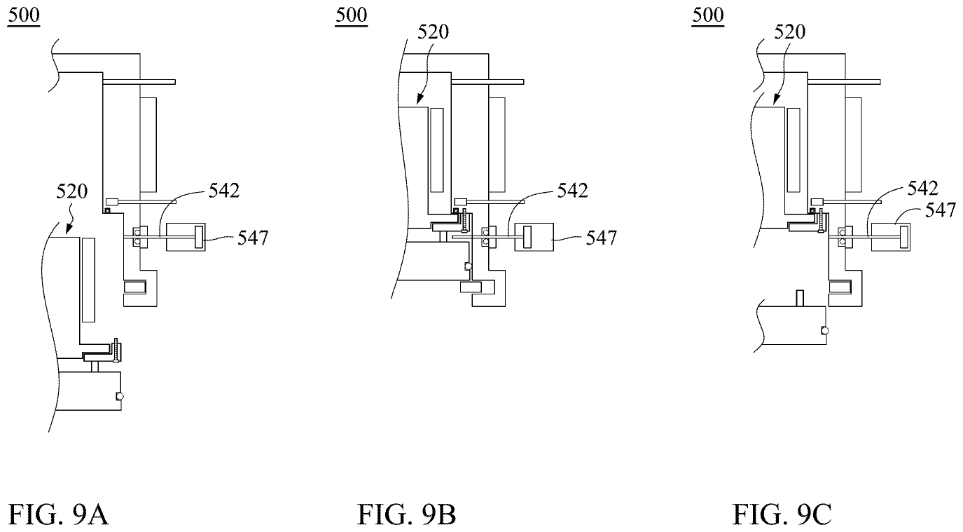

Referring to FIG. 9A to FIG. 9C, FIG. 9A to FIG. 9C are schematic diagrams showing an installation process of an inner chamber body 520 of the vertical dual-chamber annealing device 500 in accordance with the fifth embodiment of the present disclosure. The installation processes of the inner chamber body 420 of the vertical dual-chamber annealing device 400 of the fourth embodiment and the inner chamber body 520 of the vertical dual-chamber annealing device 500 of the fifth embodiment of the present disclosure are substantially the same. A difference between the two installation processes is that in the installation process of the inner chamber body 520 of the vertical dual-chamber annealing device 500 of the fifth embodiment, the moving shaft driving members 547 are used to drive the moving shafts 542 instead of the operator, such that the moving operation of the moving shafts 542 is more convenient, and the labor cost is saved.

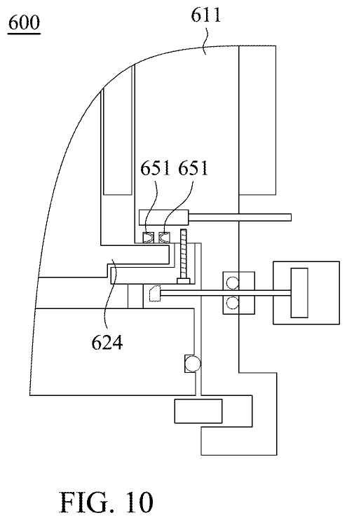

Referring to FIG. 10, FIG. 10 is a partially enlarged schematic cross-sectional view of a vertical dual-chamber annealing device 600 in accordance with a sixth embodiment of the present disclosure. A structure of the sixth embodiment of the present disclosure is substantially the same as that of the fifth embodiment. A difference between the two embodiments is that in the vertical dual-chamber annealing device 600 of the sixth embodiment, two gas-tight seal rings 651 are arranged between a top surface of a flange 624 and an outer chamber body 611, and the two gas-tight seal rings 651 are arranged in opposite directions. In one example, the gas-tight seal rings 651 are U-shaped gas-tight seal rings, and opening directions of the two gas-tight seal rings 651 are different. That is, the opening of one of the gas-tight seal rings 651 faces right, and the opening of the other one of the gas-tight seal rings 651 faces left.

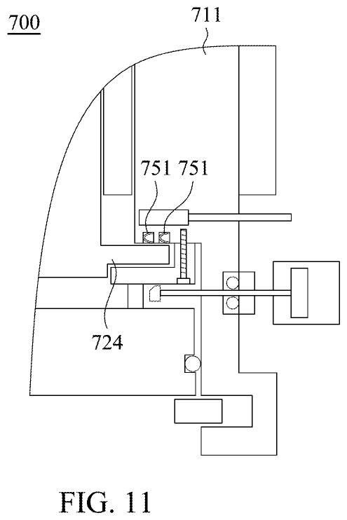

Referring to FIG. 11, FIG. 11 is a partially enlarged schematic cross-sectional view of a vertical dual-chamber annealing device 700 in accordance with a seventh embodiment of the present disclosure. A structure of the seventh embodiment of the present disclosure is substantially the same as that of the sixth embodiment. A difference between the two embodiments is that in the vertical dual-chamber annealing device 700 of the seventh embodiment, two gas-tight seal rings 751 are disposed between a top surface of a flange 724 and an outer chamber body 711, and are arranged in the same direction. In one example, the gas-tight seal rings 751 are U-shaped gas-tight seal rings, and opening directions of the two gas-tight seal rings 751 are the same, that is, the openings of the two gas-tight seal rings 751 both faces right.

According to the aforementioned embodiments, it is known that one of the advantages of the present disclosure is that the upper end of the inner chamber body of the present disclosure forms a closed end, which can enhance the uniformity of the reaction temperature. The inner chamber body can be moved upward and into the outer chamber body, and the supporting structure can support the inner chamber body and fix the inner chamber body in the outer chamber body, such that when the lower cover assembly is opened, the inner chamber body will not fall off. After the supporting of the supporting structure is removed, the inner chamber body can be moved downward and separated from the outer chamber unit. Therefore, with the inner chamber body and the supporting structure, the convenience of cleaning and replacing of the inner chamber body is increased. The gas-tight seal structure isolates the inert gas and the reactive gas, which is beneficial to the recovery and the reuse of the reactive gas.

Although the present disclosure has been disclosed above with embodiments, it is not intended to limit the present disclosure. Any person having ordinary skill in the art can make various changes and modifications without departing from the spirit and scope of the present disclosure. Therefore, the protection scope of the present disclosure should be defined by the scope of the appended claims.

What is claimed is:

1. A vertical dual-chamber annealing device, comprising:
an outer chamber unit, wherein an internal pressure that the outer chamber unit can bear is 10 bar to 1000 bar, and the outer chamber unit comprises:
an outer chamber body;
an outer chamber formed in the outer chamber body and configured to accommodate an inert gas;
a first gas injection port disposed on the outer chamber body and configured for injecting of the inert gas into the outer chamber;
a first gas discharge port disposed on the outer chamber body and configured for discharging of the inert gas out the outer chamber;
a second gas injection port disposed on the outer chamber body;
a second gas discharge port disposed on the outer chamber body;
a cooling jacket disposed on the outer chamber body;
a lower cover assembly disposed on a bottom of the outer chamber body and configured to open and close the outer chamber body; and
a plurality of through holes radially penetrating the outer chamber body;
an inner chamber body located in the outer chamber, and the inner chamber body comprising:
an inner chamber formed in the inner chamber body and configured to accommodate a reactive gas, wherein the reactive gas is injected from the second gas injection port and discharged from the second gas discharge port;
a closed end located on one end of the inner chamber body;
an open end located on another end of the inner chamber body and facing the lower cover assembly; and
a flange disposed on an outer side surface of the inner chamber body;
a temperature control unit located between the outer chamber body and the inner chamber body and configured to increase or decrease a temperature in the inner chamber;
a supporting structure located between the outer chamber body and the inner chamber body, and configured to support the flange, be connected to the outer chamber body, and fix the inner chamber body in the outer chamber body, wherein the supporting structure comprises:
a flange fastener located between the outer chamber body and the inner chamber body, and configured to support the flange and limit a movement of the inner chamber body;
a plurality of moving shafts respectively disposed in the through holes of the outer chamber body, configured to support the flange fastener, and be connected to the outer chamber body; and
a plurality of shaft sealing rings disposed in the outer chamber body and respectively surrounding the moving shafts, and configured to respectively seal the through holes; and
a gas-tight seal structure located between the outer chamber body and the inner chamber body, and configured to isolate the inert gas and the reactive gas.

2. The vertical dual-chamber annealing device of claim 1, wherein the cooling jacket is a component made of metal, and is configured to cool the outer chamber body and the shaft sealing rings.

3. The vertical dual-chamber annealing device of claim 1, wherein the lower cover assembly comprises:
a cover plate disposed on the bottom of the outer chamber body and configured to lift the inner chamber body;
a plate sealing ring disposed on the cover plate and abutting against the outer chamber, wherein the plate sealing ring is configured to seal the reactive gas, such that the reactive gas does not leak through a gap between the cover plate and the outer chamber; and
a lower cover fastener carrying the cover plate and connected to the outer chamber, and configured to fix the cover plate.

4. The vertical dual-chamber annealing device of claim 3, wherein the cover plate is a component made of metal, and the lower cover fastener is a clamp.

5. The vertical dual-chamber annealing device of claim 4, wherein a top surface of the cover plate is provided with a plurality of positioning pins, and the positioning pins are configured to support the flange fastener.

6. The vertical dual-chamber annealing device of claim 4, wherein a material of the plate sealing ring is selected from a group consisting of metallic materials, non-metallic materials, and combinations thereof.

7. The vertical dual-chamber annealing device of claim 6, wherein the material of the plate sealing ring comprises stainless steel, nickel-based alloy, rubber, polytetrafluoroethylene (PTFE), polyfluoroalkoxy (PFA), a combination of polytetrafluoroethylene and carbon fiber, a combination of polytetrafluoroethylene and carbon, or a combination of polytetrafluoroethylene and metal powder.

8. The vertical dual-chamber annealing device of claim 6, wherein a longitudinal cross-sectional shape of the plate sealing ring is circular, U-shaped, X-shaped, W-shaped, quadrilateral, or wavy-shaped.

9. The vertical dual-chamber annealing device of claim 6, wherein the inner chamber body is a component made of a non-metallic material.

10. The vertical dual-chamber annealing device of claim 9, wherein a material of the inner chamber body comprises quartz, ceramics, glass, graphite, or silicon carbide.

11. The vertical dual-chamber annealing device of claim 6, wherein the inner chamber body is a component made of a corrosion-resistant metal material.

12. The vertical dual-chamber annealing device of claim 11, wherein a material of the inner chamber body comprises nickel-based alloy or stainless steel.

13. The vertical dual-chamber annealing device of claim 1, wherein the temperature control unit comprises:
a heating element disposed on the outer side surface of the inner chamber body, and configured to heat the inner chamber body to increase the temperature in the inner chamber to an annealing temperature; and
a heat insulating material located on an outer side surface of the heating element and configured to increase a heating efficiency of the heating element.

14. The vertical dual-chamber annealing device of claim 13, wherein the temperature control unit further comprises a cooling spiral pipe, and the cooling spiral pipe is disposed on the heat insulating material and is configured to decrease the temperature in the inner chamber.

15. The vertical dual-chamber annealing device of claim 14, wherein a cooling fluid in the cooling spiral pipe is cooling water, inert gas, or air.

16. The vertical dual-chamber annealing device of claim 1, wherein the supporting structure comprises a plurality of moving shaft driving members, and the moving shaft driving members are located on an outer side surface of the outer chamber body and are respectively connected to the moving shafts.

17. The vertical dual-chamber annealing device of claim 1, wherein the flange fastener comprises:
a lower clamp located between the outer chamber body and the inner chamber body, and under the flange;
an upper clamp disposed above the lower clamp; and
a locking member passing through the upper clamp and screwed into the lower clamp, and configured to fix the upper clamp;
wherein the flange is clamped by the lower clamp and the upper clamp, and the moving shafts abut against the upper clamp.

18. The vertical dual-chamber annealing device of claim 17, wherein the gas-tight seal structure comprises a plurality of gas-tight seal rings, portions of the gas-tight seal rings are located between the lower clamp and the inner chamber body, and remaining portions of the gas-tight seal rings are located between the lower clamp and the outer chamber body.

19. The vertical dual-chamber annealing device of claim 1, wherein the flange fastener comprises:
a flange fastener body located between the outer chamber body and the inner chamber body and carrying the flange; and
a fixing bolt penetrating the flange fastener body and screwed into the outer chamber body.

20. The vertical dual-chamber annealing device of claim 19, wherein the gas-tight seal structure comprises a gas-tight seal ring, and the gas-tight seal ring is located between the flange and the inner chamber body.

21. The vertical dual-chamber annealing device of claim 20, wherein a material of the gas-tight seal ring comprises stainless steel, nickel-based alloy, rubber, polytetrafluoroethylene, polyfluoroalkoxy, a combination of polytetrafluoroethylene and carbon fiber, a combination of polytetrafluoroethylene and carbon, or a combination of polytetrafluoroethylene and metal powder.

22. The vertical dual-chamber annealing device of claim 20, wherein a longitudinal cross-sectional shape of the gas-tight seal ring is circular, U-shaped, X-shaped, W-shaped, quadrilateral, or wavy-shaped.

23. The vertical dual-chamber annealing device of claim 1, wherein the outer chamber unit comprises a cooling channel, and the cooling channel is formed in the outer chamber body and is configured to cool the gas-tight seal structure.
